(19) United States
(12) Patent Application Publication
(10) Pub. No.: US 2006/0176048 A1
(43) Pub. Date: Aug. 10, 2006

(54) Generation and use of calibration data for automated test equipment

(76) Inventors: Zhengrong Zhou, Santa Rosa, CA (US); Dan McLaughlin, Santa Rosa, CA (US); John McLaughlin, Santa Rosa, CA (US); Daniel Rishavy, Windsor, CA (US)

Correspondence Address: AGILENT TECHNOLOGIES, INC.;Intellectual Property Administration, Legal Department, DL 429, P.O. Box 7599, Loveland, CO, 80537-0599, US

(21) Appl. No.: 11/052,595

(22) Filed: Feb. 7, 2005

(51) Int. Cl. G01R 31/28

(52) U.S. Cl. 324/158.1

(57) ABSTRACT

In one embodiment, a request to perform a calibration process for automated test equipment (ATE) is received. The request is associated with one or more test setups. After receiving the request, a number of calibration padding points based on the test setups are identified. Calibration data is then generated for both the test setups and the calibration padding points. In another embodiment, a request to perform one or more calibrated test procedures using ATE is received, and in conjunction with performing at least one of the calibrated test procedures, calibration data is derived from existing calibration data.

### BACKGROUND

Prior to the manufacture and/or distribution of an electrical device (including a system or component such as a circuit board, integrated circuit, or system-on-a-chip (SOC)), the device is typically tested to determine whether it is built or functions as designed. Often, this testing is performed by automated test equipment (ATE, also called “testers”).

For the results of ATE to be meaningful, ATE needs to be calibrated. That is, the intrinsic system errors that ATE may introduce during testing under different conditions and test setups must be quantified. The data which quantifies ATE's intrinsic system errors is often referred to as “calibration data” and may comprise one or more “calibration factors”. Once generated, calibration data is used to remove ATE's intrinsic system errors from raw test data.

One way to characterize ATE's intrinsic system errors is to measure them directly. Often, this sort of calibration involves the coupling of various ATE probes to one or more known-good “calibration standards”, taking a measurement, and then comparing the measurement result to an expected measurement result.

Another way to characterize ATE's intrinsic system errors is to model them via a mathematic model. Calibration data may then be calculated from the model (although it may still be necessary to acquire certain measurements using one or more calibration standards).

Calibration data generally falls into two categories: 1) that which characterizes the core structure of ATE (e.g., the instruments and base structures of ATE—typically those parts of the ATE that are re-used when testing different devices), and 2) that which characterizes the ATE under different test setups. Test setups may specify, for example, both the physical and electrical parameters under which testing will occur, including, for example, indications of the ATE test paths that will be used during testing, as well as their configuration (including, e.g., identifications of stimulus and/or measurement paths, and indications of which ATE pins will be coupled to which pins of a device); one or more testing frequencies (including, e.g., a test frequency range); one or more modulation formats; one or more measurement bandwidths; and one or more power or voltage levels.

### SUMMARY OF THE INVENTION

In one embodiment, a method for generating calibration data for ATE commences with the receipt of a request to perform a calibration process for the ATE (the request being associated with one or more test setups). A number of calibration padding points based on the test setups are then identified, and calibration data is generated for both the test setups and the calibration padding points.

In another embodiment, a method for performing one or more calibrated test procedures using ATE comprises receiving a request to perform one or more calibrated test procedures using the ATE, and in conjunction with performing at least one of the calibrated test procedures, deriving calibration data from existing calibration data.

Other embodiments are also disclosed.

### BRIEF DESCRIPTION OF THE DRAWINGS

Illustrative embodiments of the invention are illustrated in the drawings, in which:

FIG. 1 illustrates an exemplary method for generating calibration data for ATE;

FIG. 2 illustrates a method for performing one or more calibrated test procedures using ATE;

FIG. 3 illustrates a first exemplary plot of calibration data; and

FIG. 4 illustrates a second exemplary plot of calibration data.

### DETAILED DESCRIPTION

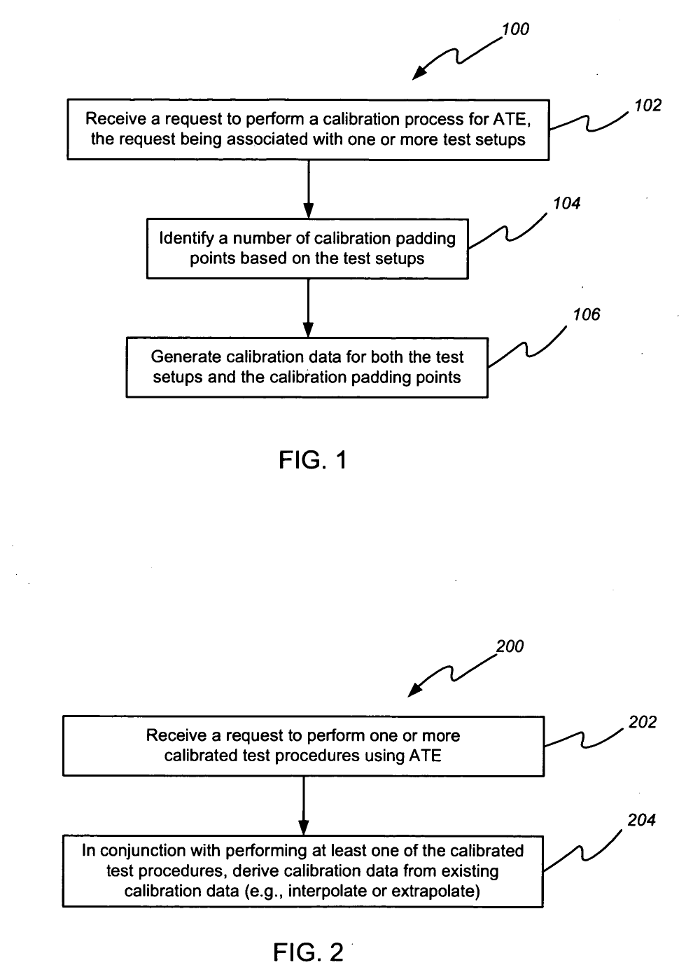

Prior to production testing of a device, a suite of tests for testing the device must be developed. During this process, test setups may be reconfigured numerous times. Each time test setups are reconfigured, ATE must be re-calibrated in light of the reconfigured test setups. These numerous re-calibrations are time consuming, and can substantially increase the “time-to-market” cycle of a new device. However, in the absence of calibration data for new test setups, a test developer cannot determine whether his or her new test setups are useful. FIG. 1 therefore illustrates a new method 100 for generating calibration data for ATE.

The method 100 commences with the receipt 102 of a request to perform a calibration process for ATE. The request is associated with one or more test setups. In some cases, the test setups may be specified by a test developer as part of his or her request to perform a calibration process. In other cases, the test setups may be identified by software that identifies the set of test setups that have been loaded into ATE.

After receipt of a request to perform a calibration process, the method 100 continues with the identification 104 of a number of calibration padding points. The calibration padding points are based on the test setups that are associated with the request. For example, where the test setups specify more than one value for a test setup attribute, such as frequencies of one and six gigahertz (1 GHz and 6 GHz), these values may be identified as endpoints of a calibration range, and a number of calibration padding points falling within the range may be identified. Alternately (or additionally), calibration padding points falling outside of the range may be identified.

If only one value is provided for a test setup attribute, calibration padding points may be identified “about” the value. That is, calibration padding points may be identified on either side of the value, or the value may be treated as the upper or lower endpoint of a calibration range.

In some cases, calibration padding points may be identified based on a user-specified (or default) step size, such as 100 MHz. Thus, in the context of test setup attributes of 1 GHz and 6 GHz, calibration padding points of 1.1 GHz, 1.2 GHz, 1.3 GHz, and so on might be identified. In other cases, calibration padding points may be identified in response to a user-specified (or default) number of padding points to be identified (e.g., ten padding points).

As alluded to above, calibration padding points may be based on user-specified data, such as a user-specified step size or number of padding points that is provided in the context of a calibration request (e.g., with the calibration request, or in response to computer prompting after receipt of the request). Alternately (or additionally), calibration padding points may be based on default rules that are specified prior to receipt of a calibration request. These default rules may be fixed rules or programmable rules.

After the identification 104 of calibration padding points, the method 100 then continues with the generation 106 of calibration data for both the test setups associated with the calibration request, as well as the calibration padding points. In this manner, additional calibration data can be generated as part of a single calibration process, potentially 1) reducing the time required to generate the calibration data, and 2) generating additional calibration data that might be useful as a test developer reconfigures his or her test setups during test development. By way of example, FIG. 2 illustrates a method 200 in which the calibration data generated by the method 100 may be used.

The method 200 commences with the receipt 202 of a request to perform one or more calibrated test procedures using ATE. The calibrated test procedures may comprise, for example, the delivery of one or more stimulus and the measurement of one or more responses. For some of the test procedures, necessary calibration data may not exist. However, instead of triggering a new calibration procedure, the calibration data is derived 204 from existing calibration data. For example, the calibration data may be derived by interpolating between two or more existing pieces of calibration data, or the calibration data may be derived by extrapolating outside a range of the existing calibration data.

The method 200 may be run following the method 100, such that new calibration data is interpolated and/or extrapolated from calibration data that was generated based on test setups and/or calibration padding points. In other cases, the method 200 may be run in the absence of executing method 100, and new calibration data may be interpolated and/or extrapolated solely from calibration data based on test setups.

Regardless of the context in which the method 200 is performed, data interpolation may be undertaken in a variety of ways. For example, new calibration data may be interpolated or extrapolated linearly—by identifying a calibration data point that falls between two pieces of existing calibration data, or by identifying a calibration data point that lies outside of a range defined by two pieces of existing calibration data. Alternately, a line or non-linear curve may be fit to a plurality of pieces of existing calibration data (e.g., using a polynomial model, or some other model based on exponential, trigonometric or other type of function).

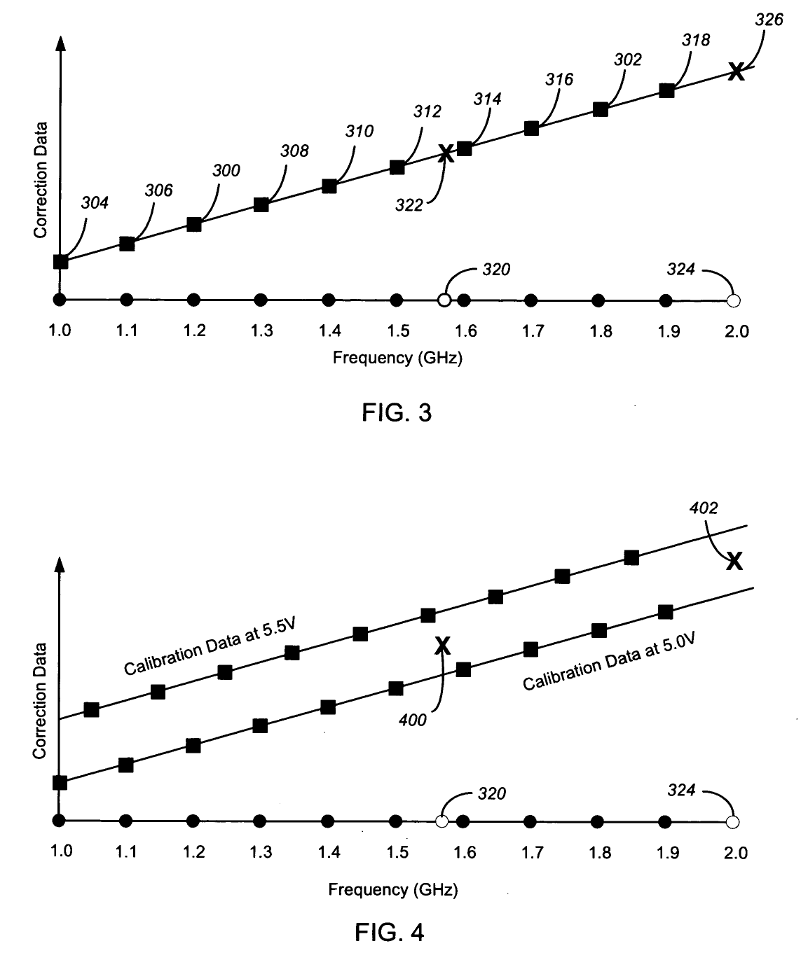

FIG. 3 illustrates a first application of the method 200. As shown, calibration data exists for a plurality of different frequencies. Some of the data points 300, 302 may be based on previous or current test setups, whereas other data points 304-318 may be based on calibration padding points for which tests setups may never have existed. If a request to perform a calibrated test procedure specifies that a test is to be performed at 1.575 GHz (point 320), a linear interpolation between the existing calibration data points results in the new calibration data point 322 being generated. Similarly, if a request to perform a calibrated test procedure specifies that a test is to be performed at 2.0 GHz (point 324), a liner extrapolation from the existing calibration data points results in the new calibration data point 326 being generated.

FIG. 4 illustrates a second application of the method 200. This example is similar to that shown in FIG. 3, but for the fact that calibration data now depends on both a frequency attribute and a voltage attribute. If a request to perform a calibrated test procedure specifies that a test be performed at 1.575 GHz and 5.25 Volts (V), an interpolation may be made in both a frequency context and a voltage context, thereby resulting in the new calibration data point 400 being generated. Likewise, if a request to perform a calibrated test procedure specifies that a test be performed at 2.0 GHz and 5.25 Volts (V), an extrapolation may be made in both a frequency context and a voltage context to generate the new calibration data point 402.

As new calibration data is generated, it may be stored in a database along with the existing calibration data from which it was interpolated or extrapolated (and may then be used for later interpolations or extrapolations), or it may be stored in a separate database of derived data (such that actual and derived calibration data is kept separate).

In some cases, one or more databases of calibration data may be stored within ATE memory. In other cases, one or more databases of calibration data may be stored apart from ATE, thereby freeing the ATE's resources.

In one embodiment, the methods shown in FIG. 1, FIG. 2, or any variant thereof, may be embodied in sequences of instructions stored on machine-readable media (e.g., one or more fixed disks, removable media such as compact discs (CDs) or digital versatile discs (DVDs), random-access or read only memories, or any combination thereof, whether in a single location, on a single machine, or distributed across a network). When executed by a machine such as a computer system, the sequences of instructions then cause the machine to perform the actions of the method 100 or 200. By way of example, the machine which executes the sequences of instructions may be a system-on-a-chip (SOC) tester, such as the Agilent 93000 SOC Tester, or an integrated circuit tester, such as the Agilent 84000 Radio Frequency (RF) Integrated Circuit tester. The 93000 and 84000 are both available from Agilent Technologies, Inc., which is headquartered in Palo Alto, Calif., USA.

Successive calibrations of ATE can be extremely time-consuming, especially during test development. The use of calibration padding points to proactively generate additional calibration data, and/or the interpolation/extrapolation of existing calibration data to generate new calibration data, can therefore save a significant amount of time and decrease a device's “time-to-market”.

What is claimed is:

1. A method for generating calibration data for automated test equipment (ATE), comprising:
receiving a request to perform a calibration process for the ATE, the request being associated with one or more test setups;
identifying a number of calibration padding points based on the test setups; and
generating calibration data for both the test setups and the calibration padding points.

2. The method of claim 1, wherein the test setups comprise first and second values for a given test setup attribute, and wherein the method further comprises:
identifying the first and second values as endpoints of a calibration range; and
identifying at least some calibration padding points that fall within the calibration range.

3. The method of claim 1, wherein the test setups specify first and second values for a given test setup attribute, and wherein the method further comprises:
identifying the first and second values as endpoints of a calibration range; and
identifying at least some calibration padding points that are outside of the calibration range.

4. The method of claim 1, wherein the test setups provide a value for a first test setup attribute, and wherein the calibration padding points are identified about the value.

5. The method of claim 1, further comprising, receiving a user-specified step size; wherein the calibration padding points are identified by applying the step size to a value for a first test setup attribute.

6. The method of claim 1, further comprising, receiving a user-specified number of padding points to be identified.

7. The method of claim 1, wherein the calibration padding points are based on user-specified data, provided in the context of the request to perform the calibration process.

8. The method of claim 1, wherein the calibration padding points are based on default rules specified prior to receipt of the request to perform the calibration process.

9. The method of claim 1, further comprising:
receiving a request to perform one or more calibrated test procedures using the ATE; and
in conjunction with performing at least one of the calibrated test procedures, deriving calibration data by interpolating between two or more pieces of existing calibration data.

10. The method of claim 9, wherein said interpolation comprises fitting a curve to the existing calibration data.

11. The method of claim 1, further comprising:
receiving a request to perform one or more calibrated test procedures using the ATE; and
in conjunction with performing at least one of the calibrated test procedures, deriving calibration data by extrapolating outside a range of the existing calibration data.

12. The method of claim 11, wherein said extrapolation comprises fitting a curve to the existing calibration data.

13. A method for performing one or more calibrated test procedures using automated test equipment (ATE), comprising:
receiving a request to perform one or more calibrated test procedures using the ATE; and
in conjunction with performing at least one of the calibrated test procedures, deriving calibration data from existing calibration data.

14. The method of claim 13, wherein said calibration data is derived by interpolating from between two or more pieces of existing calibration data.

15. The method of claim 14, wherein said interpolation comprises fitting a curve to the existing calibration data.

16. The method of claim 13, wherein said calibration data is derived by extrapolating outside a range of the existing calibration data.

17. The method of claim 16, wherein said extrapolation comprises fitting a curve to the existing calibration data.

18. A number of machine-readable media having stored thereon sequences of instructions that, when executed by a machine, cause the machine to perform the actions of:
receiving a request to perform a calibration process for automated test equipment (ATE), the request being associated with one or more test setups;
identifying a number of calibration padding points based on the test setups; and
generating calibration data for both the test setups and the calibration padding points.

19. The machine-readable media of claim 18, wherein the actions performed during execution of the sequence of instructions further comprise, receiving a user-specified step size; and wherein the calibration padding points are identified by applying the step size to a value for a first test setup attribute.

20. The machine-readable media of claim 18, wherein the actions performed during execution of the sequence of instructions further comprise:
receiving a request to perform one or more calibrated test procedures using the ATE; and
in conjunction with performing at least one of the calibrated test procedures, deriving calibration data from existing calibration data.
